(19) United States
(12) Patent Application Publication
(10) Pub. No.: US 2018/0104880 A1
(43) Pub. Date: Apr. 19, 2018

(54) FILTER MEDIUM, FILTER MEMBER PROVIDED WITH FILTER MEDIUM, AND PRODUCTION METHOD FOR RESIN FILM USING FILTER MEDIUM

(71) Applicant: NAGASE & CO., LTD., Osaka-shi, Osaka (JP)

(72) Inventors: Yoshiaki FUKUDA, Osaka (JP); Shintaro KASUYA, Osaka (JP)

(73) Assignee: NAGASE & CO., LTD., Osaka-shi, Osaka (JP)

(21) Appl. No.: 15/506,021

(22) PCT Filed: May 24, 2016
(86) PCT No.: PCT/JP2016/065251

§ 371 Date: Feb. 23, 2017

(30) Foreign Application Priority Data
Jun. 16, 2015 (JP) 2015-121152

(51) Int. Cl. B29C 47/68; B01D 39/20; B01D 29/39; B01D 29/00; C23C 14/34; C23C 14/06

(52) U.S. Cl. CPC B29C 47/68; B01D 39/2044; B01D 29/39; C23C 14/0641; C23C 14/34; C23C 14/0635; B01D 29/0093

(57) ABSTRACT

An object of the present invention is to prevent precipitation of antimony metal comprised in a molten resin and to prevent product defects of a resin film made of the molten resin due to the contamination of the antimony metal. According to the present invention, a filter medium for filtration of a molten resin containing antimony is provided, and the filter medium is formed of a material not substantially comprising molybdenum.

### TECHNICAL FIELD

The present invention relates to a filter medium, a filter member provided with the filter medium, and a production method for a resin film using the filter medium.

### BACKGROUND ART

Apparatuses for producing a resin film from a molten resin are conventionally known. In Patent Literature 1, a filter element for filtration of a molten resin is disclosed.

A filter medium for filtration of a molten resin is mainly produced using SUS316L, and the use of SUS316L is mainly intended to achieve a good corrosion resistance and a good acid resistance and to prevent stress corrosion, pitting corrosion, and intergranular corrosion.

### CITATION LIST

### Patent Literature

Patent Literature 1: JP 2009-279517 A

### SUMMARY OF INVENTION

### Technical Problem

However, when SUS316L is used for a filter medium for filtration of a molten resin, antimony metal precipitates on the filter medium surface, thereby resulting in an increase in the filtration pressure in a relatively short period of time. In some cases, the antimony metal precipitate comes off the filter medium surface and contaminates a filtered molten resin. Moreover, every time the increase of the filtration pressure or the contamination of a filtered molten resin by antimony metal etc. occurs, the filter medium is required to be replaced with a new one, leading to a cost problem.

The present invention was made in order to solve the above problems, and thus an object of the present invention is to provide a filter medium which does not allow the precipitation of antimony metal during the filtration of a molten resin containing antimony, a filter member provided with the filter medium, and a production method for a resin film using the filter medium.

### Solution to Problem

The present inventors carried out extensive investigations on the basis of the hypothesis that the precipitation of antimony metal is likely to be related to the materials of filter media, consequently found that, in cases where molybdenum is comprised in the filter medium material, the antimony metal in an antimony compound comprised in a molten resin is likely to precipitate on the filter medium surface, and then completed the present invention.

The present invention 1 is a filter medium for filtration of a molten resin containing antimony. The filter medium is formed of a material not substantially comprising molybdenum. Herein, “not substantially comprising” means that, for example, in quantitative analysis of elements comprised in the material using a publicly known method, it is acceptable that molybdenum is comprised within a range of an error which can inevitably occur at the time of measurement, such as an error in which measurement values are biased due to a specific cause including the individual specificity of an analyzing device and the peculiarity of an analyzing method (so-called a systematic error) and an error due to dust or dirt attached to an analyzing device (so-called an accidental error).

The present invention 2 is a filter member provided with the filter medium of the present invention 1. Herein, the filter medium means a porous body directly used for filtration, and the filter member means, for example, a member which comprises the filter medium as a component and is used for filtration.

The present invention 3 is a resin film production method. The present invention 3 comprises a step of producing a molten resin containing antimony, a step of filtering the molten resin produced in the production step, and a step of forming a resin film from the molten resin filtered in the filtration step, the filtration step being a step of filtering the molten resin using a filter medium formed of a material not comprising substantially molybdenum.

### Advantageous Effects of Invention

The present inventors found that the reason why antimony metal (Sb) is likely to precipitate on the filter medium surface in the filtration of a molten resin comprising diantimony trioxide (Sb₂O₃) is that molybdenum acts as a reducing agent promoting a reducing reaction in which “Sb₂O₃” is reduced to “2Sb” in the ion-exchange reaction between iron (Fe) comprised in the filter medium and antimony (Sb) in diantimony trioxide, though the details about the action of molybdenum are not clear. According to the present invention 1, a material not substantially comprising molybdenum, which element can cause precipitation of antimony metal, is used to forma filter medium. Accordingly, a molten resin can be filtered without precipitation of antimony metal on the filter medium surface.

The amount of antimony precipitated on the filter medium of the present invention 1 is preferably 1000 counts or less of X-rays at a wavelength specific to antimony when measured with an Electron Probe Micro Analyzer (EPMA) method. Prior to the measurement, the filter medium is immersed in an ethylene glycol solution containing 2% by weight diantimony trioxide, left to stand in the solution kept at 170° C. for 24 hours, and then taken from the solution. In the EPMA method, X-rays are generated by electron irradiation to the filter medium and the number of counts of X-rays at a wavelength specific to antimony is measured with an X-ray spectrometer. When the amount is 1000 counts or less, the increase in filtering pressure can be reduced.

The amount of iron dissolved from the filter medium of the present invention 1 in an ethylene glycol solution containing 2% by weight diantimony trioxide is preferably 20 ppm or less, and more preferably 10 ppm or less when measured after 24-hour immersion of the filter medium in the solution kept at 170° C. When a filter medium from which more than 20 ppm of iron dissolves as measured in the above manner is used as a filter medium for filtration of a molten resin containing antimony, antimony metal precipitates on the filter medium surface for a relatively short period of time, thereby resulting in an increase in the filtering pressure. In some cases, the antimony metal precipitate comes off the filter medium surface and contaminates a filtered molten resin. Moreover, in cases where the filter member has been cleaned more times, the filtering pressure can increase in a shorter period of time. These are fatal disadvantages. Therefore, it is preferable to prevent the precipitation of antimony metal on the filter medium surface. Accordingly, the amount of iron dissolved from the filter medium in an ethylene glycol solution containing 2% by weight diantimony trioxide is preferably 20 ppm or less when measured after 24-hour immersion of the filter medium in the solution kept at 170° C.

For the production of a filter medium, stainless steel SUS316L (containing 2 to 3% by mass molybdenum) is conventionally used as a material so that the filter medium has rust prevention, acid resistance, and the like. In cases where SUS316L is used for a filter medium for filtration of a polyester molten resin, the precipitation of antimony metal on the filter medium surface easily occurs and causes the clogging of the filter medium, leading to an increase in the filtering pressure in a relatively short period of time. Moreover, the antimony metal precipitate comes off the filter medium surface and contaminates a molten resin, which results in foreign matter defects on the resin film surface. These are fatal disadvantages.

Generally, stainless steel is a metal containing 10 to 12% or more chromium (Cr) and/or nickel (Ni), which can induce passivation, and the other 80% or more iron as a major metal. When an easily ionizable element iron, which is comprised in a percentage of 80% or more in stainless steel, comes into contact with a metal which is not easily ionizable, such as antimony (Sb), platinum (Pt), copper (Cu), osmium (Os), and in some situations, germanium (Ge) and titanium (Ti) at high temperature, an ion-exchange reaction will occur.

As a result, the iron comprised in the material forming a filter medium dissolves as an iron ion, and the iron ions come to be mixed into a molten resin. Around an area where iron is dissolved on the filter medium surface, a heavy metal such as antimony precipitates. Since a heavy metal, such as antimony, is precipitated on the filter medium surface, the amount of antimony precipitated on the filter medium surface can be detected. Moreover, since the iron ions are dissolved in the molten resin, the amount of the iron ions in the molten resin can be determined by detection of the concentration of the iron in the molten resin. Thus, the clogging level of the filter medium can be determined in an indirect manner, and thereby the appropriate timing for replacement of the filter medium can be predicted.

In consideration of the above problems, “a material comprising an element less likely to promote an ion-exchange reaction of the iron comprised in the material” is required to be selected as the material of the filter medium. Among stainless steels, austenitic stainless steels containing as relatively much as about 15 to 20% chromium (Cr) and 8 to 15% nickel (Ni) have good corrosion resistance and good acid resistance and can be passivated to prevent the reaction. Therefore, such austenitic stainless steels are preferred as the basic material of the filter medium of the present invention.

However, some austenitic stainless steels containing 15 to 20% chromium (Cr) and 8 to 15% nickel (Ni) are prone to ion-exchange reaction. Such austenitic stainless steels contain a specific element component inducing ion-exchange reaction, and ion-exchange reaction of the iron with another metal such as antimony occurs intensively around the specific element.

Examples of such an element which induces ion-exchange reaction include molybdenum (Mo), manganese (Mn), and sulfur (S), and moreover, aluminum (Al), titanium (Ti), phosphorus (P), and silicon (Si), and in addition, carbon (C) are likely to induce ion-exchange reaction. Therefore, a stainless steel not substantially containing any of these elements is preferably selected as the material of the filter medium. “Not substantially containing” means that it is acceptable that the above elements are contained within a range of an error which can inevitably occur at the time of the measurement as described above. It is important that the stainless steel selected as the material of the filter medium not contain the above elements. For example, the amount of carbon (C) contained in the stainless steel is 0.08% or less and preferably 0.03% or less. The amount of molybdenum (Mo) contained in the stainless steel is 0.3% or less, and preferably molybdenum (Mo) is not substantially contained in the stainless steel.

In contrast to the above elements, some elements inhibit ion-exchange reaction. Examples of the elements include copper (Cu), niobium (Nb), bismuth (Bi), lead (Pb), and tellurium (Te), and the stainless steel as the material of the filter medium preferably contains at least one of copper, niobium, bismuth, lead, and tellurium as an element.

The stainless steel not prone to ion-exchange reaction may be a stainless steel or a composite stainless steel selected from SUS304, SUS304L, SUS304LN, SUS304Cu, SUS304N1, SUS304N2, SUS304J1, SUS304J2, SUS304BF, SUS304FL, SUS347, SUS321, SUS630J2, ASK3000T, and SUSXM15J1. Among the above, the stainless steel which is especially not prone to ion-exchange reaction is SUS304L, SUS304LN, or SUS304Cu.

Understandably, the metal material comprised in the filter medium of the present invention may have been subjected to a single surface treatment selected from chrome plating, nickel plating, copper plating, ceramic composite nickel plating, titanium nitride sputtering, and silicon carbide sputtering, or a composite surface treatment thereof. The plating method is preferably an electroless plating method.

According to the present invention 2, a filter member comprising, as a component, a filter medium formed of a material not substantially comprising molybdenum is provided. The use of the filter member allows filtration of a molten resin containing antimony without precipitation of antimony metal on the filter medium surface.

Present invention 3 comprises a step of producing a molten resin containing antimony, a step of filtering the molten resin produced in the production step, and a step of forming a resin film from the molten resin filtered in the filtration step, the filtration step being a step of filtering the molten resin using a filter medium formed of a material not comprising substantially molybdenum. In the production of a resin film from a molten resin containing antimony, precipitation of antimony metal on the filter medium surface in the filtration of the molten resin can be prevented by use of a filter medium formed of a material which comprises stainless steel and does not substantially comprise molybdenum. Thus, quality defects of the resin film can be prevented.

### BRIEF DESCRIPTION OF DRAWINGS

FIG. 1 shows schematic views of a filter member provided with a filter medium of an embodiment of the present invention. (a) is a front view, (b) is a cross-section view, and (c) is an enlarged view around a hub part.

FIG. 2 is a cross-section view of a filter using the filter member of an embodiment.

FIG. 3 is a schematic view of an apparatus for producing a resin film using the filter of an embodiment.

### DESCRIPTION OF EMBODIMENTS

The embodiments of the present invention will be described in details below, referring to the drawings. The present invention is not limited to the embodiments described below, and various variations and modifications can be made without departing from the technical scope of the present invention.

### Filter Medium

A filter medium (20) in an embodiment is intended for filtration of a molten resin containing antimony. The filter medium (20) is a sintered stainless metal non-woven fabric formed by sintering of a wire rod of SUS304L. The wire rod of SUS304L is one obtained by cutting work.

The filter medium (20) has a filtering accuracy of 1 to 80 μm, the filtering accuracy herein being such a particle dimeter that 98% of particles having the dimeter can be collected in a single pass test. The filter medium (20) is a depth-type filter medium, and the collection efficiency can be adjusted by changing the weight per unit area of the filter medium (20) and/or the structure of the filter medium (20).

Moreover, as described above, molybdenum comprised in stainless steel causes precipitation of antimony metal, and therefore a wire rod of SUS304L, a molybdenum-free stainless steel, is used for the filter medium (20) of the embodiment. Accordingly, a molten resin containing antimony can be filtered without precipitation of antimony metal on the filter medium surface.

Herein, the wire rod used for the filtering medium (20) is not limited to SUS304L. The wire rod used for the filtering medium (20) may be any stainless steel not comprising molybdenum, and is preferably, for example, SUS304, SUS304LN, SUS304Cu, SUS304N1, SUS304N2, SUS347, SUS304J1, SUS304J2, SUS304BF, SUS304FL, SUS321, ASK3000T, SUS630J2, or SUSXM15J1 in addition to SUS304L.

The raw material of the molten resin containing antimony is preferably a thermoplastic resin. The raw material of the molten resin is preferably polyester, polyphenylene sulfide, polyamide, polypropylene, ethylene vinyl acetate, alicyclic olefin, or acrylic.

The molten resin containing antimony is preferably a polyester resin having an ester bond, i.e. an ester group-containing polymer obtained by polycondensation of a dicarboxylic acid with a diol or a hydroxycarboxylic acid. Examples of the dicarboxylic acid component include terephthalic acid, isophthalic acid, adipic acid, azelaic acid, sebacic acid, 2,6-naphthalenedicarboxylic acid, 1,4-cyclohexanedicarboxylic acid, and the like. Examples of the diol component include ethylene glycol, 1,4-butanediol, diethylene glycol, triethylene glycol, neopentyl glycol, 1,4-cyclohexanedimethanol, polyethyleneglycol, and the like. Major examples of the hydroxycarboxylic acid include p-hydroxybenzoic acid, 6-hydroxy-2-naphthoic acid, and the like. Major examples of the polyester resin include polyethylene terephthalate (PET), polyethylene naphthalate (PEN), polycyclohexylenedimethylene terephthalate (PCT), polybutylene terephthalate (PBT), modified bodies thereof, and the like.

The polymerization catalyst used for polymerization to give PET is an antimony metal compound, a germanium compound, a titanium compound, an aluminum compound, or the like, and an antimony (Sb) catalyst is dominantly often used for preparing PET raw materials in the resin film field throughout the world. In some cases, to PET raw materials prepared without the use of an antimony compound as a polymerization catalyst, an antimony compound is added for impartment of flame resistance and colorability.

The filter medium (20) of the embodiment is not limited to a sintered metal non-woven fabric, and may be formed of, for example, a stainless metal sintered body obtained by powder processing of a stainless steel not comprising molybdenum and sintering of the resulting powder. The filter medium (20) may also be a laminated body obtained by lamination of sintered stainless metal wire gauzes which are formed in a net shape using a sintered wire rod of a stainless steel not comprising molybdenum.

### Filter Member

Next, a filter member (10) provided with the above-mentioned filter medium (20) will be described.

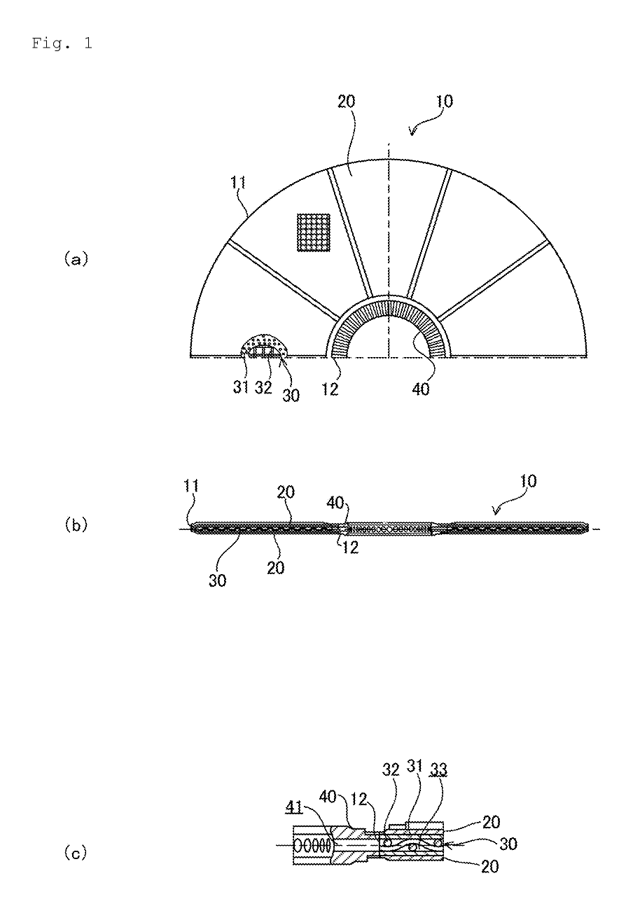

The filter member (10) is provided with the above-mentioned filter medium (20) made of sintered metal non-woven fabric, a filter retainer (30), and a hub part (40), as shown in FIG. 1 (a). The filter member (10) is formed in an annular shape having an outside diameter of 304 mm, an inside diameter of 63.5 mm, and a thickness of 7.4 mm.

The filter medium (20) made of sintered metal non-woven fabric is formed in an annular shape. The filter medium (20) made of sintered metal non-woven fabric is supported on each axial end surface of the filter retainer (30). The filter medium (20) made of sintered metal non-woven fabric and the filter retainer (30) are arranged in a concentric fashion. As shown in FIG. 1 (b), the outer peripheral edge of the filter medium (20) made of sintered metal non-woven fabric is joined to the outer peripheral edge of the filter retainer (30) by welding all around, and thus, the filter member (10) is closed at the outer peripheral end (11). Moreover, at the inner peripheral end (12) of the filter member (10), the inner peripheral edge of the filter medium (20) made of sintered metal non-woven fabric and the inner peripheral edge of the filter retainer (30) are joined to a cylindrical hub part (40) by welding.

The filter retainer (30) is a laminated body obtained by lamination of a plurality of annular porous plates (31) and a plurality of annular wire gauzes (32) in the thickness direction (see FIG. 1 (a)). Inside the laminated body, as shown in FIG. 1 (c), a fluid passage (33) is formed so that a pore of the porous plate (31) is in communication with an opening of the wire gauze (32). Moreover, the hub part (40) has hub holes (41) formed over the entire periphery, the hub holes penetrating through the hub part in the radial direction. The hub hole (41) is in communication with the fluid passage (33) of the laminated body of the filter retainer (30).

In the filter member (10), a molten resin is filtered through the filter medium (20) made of sintered metal non-woven fabric and then flows into the fluid passage (33) in the filter retainer (30). The molten resin flows through the fluid passage (33) in the filter retainer (30) inward from the outer peripheral side in the radical direction, and discharges outside the filter member (10) through the hub hole (41) of the hub part (40).

Herein, since SUS304L as the material of the filter medium (20) made of sintered metal non-woven fabric in the filter member (10) does not comprise molybdenum, an element causing precipitation of antimony metal, antimony metal will not precipitate or adhere to the filter medium (20) made of sintered metal non-woven fabric even if antimony is comprised in the molten resin.

Moreover, the use of a stainless steel not comprising molybdenum, for example, SUS304L for forming of the filter retainer (30) and the hub part (40) can surely prevent precipitation of antimony metal in the filter member (10).

### Filter

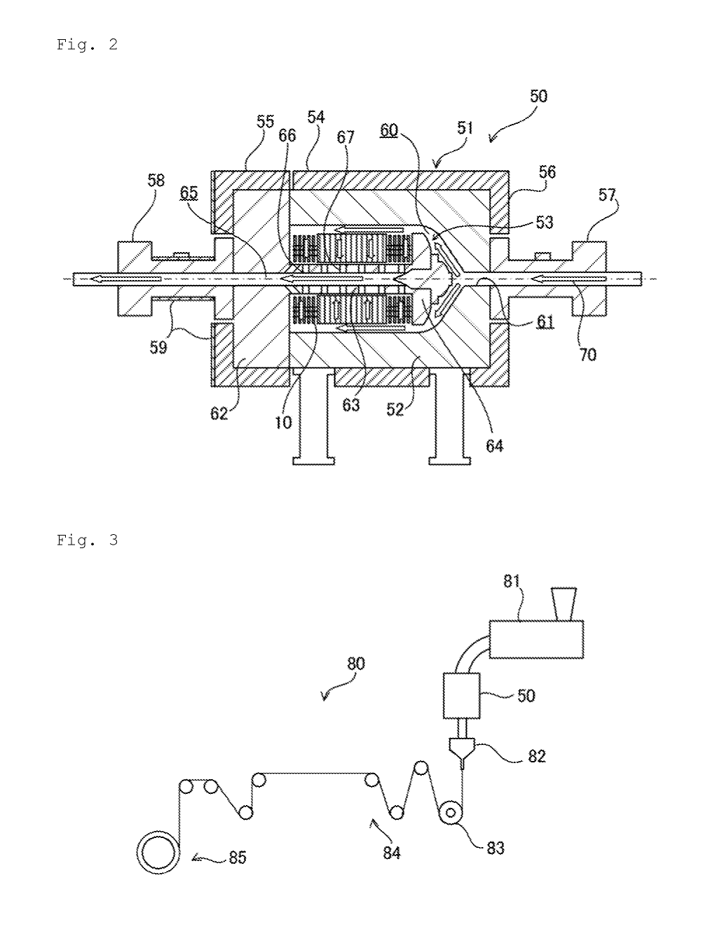

Next, a filter (50) having the above-mentioned filter member (10) will be described. The filter (50) is provided with a casing (51), a filter case (52), and a filter assembly (53), as shown in FIG. 2. The filter case (52) and the filter assembly (53) are housed within the casing (51) in such a state that they are combined.

The casing (51) has a bottomed cylindrical body part (54) and a lid part (55). The lid part (55) is removably attached to an opening end of the body part (54). The body part (54) is connected to an inlet passage part (57), the inlet passage part passing through a bottom (56) of the body part. The lid part (55) is connected to an outlet passage part (58), the outlet passage part passing through the axial end of the lid part. Moreover, the lid part (55) and the outlet passage part (58) are provided with heaters (59) for heating a molten resin (70).

The filter case (52) is formed in a column shape and in the central area, a recessed part (60) for housing the filter assembly (53) is formed. In the recessed part (60), the bottom is formed in a funnel shape, and in the central part of the funnel-shaped inside, a penetrating part (61) is formed.

The filter assembly (53) is provided with a cylindrical base (62), a pillar (63), a protecting member (64), and a plurality of the filter members (10) laminated in the thickness direction. In the base (62), the pillar (63) is fixed to the central part. To the end of the pillar (63), the protecting member (64) is fixed. A plurality of the filter members (10) are located between the base (62) and the protecting member (64) in such a state that the pillar (63) is inserted through the filter members. These filter members (10) are arranged at regular intervals in the axial direction of the pillar (63). A spacer provided between the filter members (10) generates a gap between the filter members (10), which results in prevention of the contact between the filter media (20) made of sintered metal non-woven fabric in the adjacent filter members (10).

In the filter assembly (53), a through passage (65) where the molten resin (70) flows is formed in the central area. The through passage (65) is closed at one end (in the right side in FIG. 2), and is in communication with the outlet passage part (58) at the other end (in the left side in FIG. 2).

The pillar (63) has a plurality of pillar holes (66) formed on the outer peripheral surface. Each pillar hole (66) is in communication with the through passage (65) inside the pillar (63). Moreover, between the pillar (63) and the filter members (10), communication members (67) allowing connection between the pillar holes (66) of the pillar (63) and the hub holes (41) of the filter members (10) are formed.

In the filter (50), the molten resin (70) flows from the inlet passage part (57) into the recessed part (60) of the filter case (52) through the penetrating part (61) inside the filter case (52). The molten resin (70) flowing into the recessed part (60) enters an axial gap between the filter members (10), and then enters the filter medium (20) which is made of sintered metal non-woven fabric and provided in the filter member (10) located on each side of the axial gap, resulting in the filtration of the molten resin.

The filtered molten resin (70) flows into the fluid passage (33) in each filter retainer (30), flows through the fluid passage (33) inward from the outer peripheral side in the radical direction, and flows from the hub hole (41) of the hub part (40) into the through passage (65) inside the pillar (63) via the communicating member (67) and the pillar hole (66) of the pillar (63). The molten resin (70) flowing into the through passage (65) inside the pillar (63) discharges from the filter (50) through the outlet passage part (58).

The use of a stainless steel not comprising molybdenum, for example, SUS304L for forming the casing (51), the filter case (52), and the base (62), the pillar (63), and the protecting member (64) of the filter assembly (53) in the filter (50) can surely prevent precipitation of antimony metal in the filter (50).

### Production Apparatus for Resin Film

Next, a resin film production apparatus (80) for producing a resin film using the filter (50) will be described. As shown in FIG. 3, the resin film production apparatus (80) is provided with an extruder (81), the above-mentioned filter (50), a film forming machine (82), a cooling machine (83), a stretching machine (84), and a take-up machine (85).

In the extruder (81), heat and shearing force are applied to a solid resin, and the resulting molten resin is extruded. The molten resin comprises antimony. The molten resin extruded by the extruder (81) is filtered with the filter (50) for removal of impurities. Herein, the filter medium (20) used in the filter (50) is formed of SUS304L. SUS304L does not comprise molybdenum, an element causing precipitation of antimony metal. Accordingly, during the filtration with the filter (50), antimony metal will not precipitate or adhere to the filter medium (20). The material used for forming the filter medium (20) is not limited to SUS304L, and may be any stainless steel not comprising molybdenum.

The molten resin filtered with the filter (50) is extruded from a slit nozzle provided in the film forming machine (82) and formed into a film. Herein, the nozzle may be formed of a stainless steel not comprising molybdenum, for example, SUS304L, as is the case with the filter medium (20) used in the filter (50). The use of such a stainless steel can prevent precipitation of antimony metal in the nozzle part. Moreover, in the resin film production apparatus (80), a part which the molten resin is in contact with may be formed of a stainless steel not comprising molybdenum. The use of such a stainless steel can surely prevent precipitation of antimony metal in the resin film production apparatus (80).

The film-shaped molten resin formed by extrusion from the nozzle of the film forming machine (82) is cooled with the drum-like cooling machine (83), and then stretched in any direction at any stretching ratio using the stretching machine (84) having a plurality of rotating rolls, to give a desired film. The edges at both the ends of the obtained film are cut, and then the film is taken up with the take-up machine (85).

### Film Production Method

Next, a method for producing a resin film using the above-mentioned filter medium will be described. The resin film production method comprises a step of producing a molten resin, a step of filtering the molten resin, and a step of forming a resin film from the filtered molten resin.

The production step is a step of producing a molten resin containing antimony. In the production step, a molten resin is produced by application of heat and shearing force to a solid resin. Moreover, to the molten resin, antimony is added as a polycondensation catalyst. Herein, the raw material of the molten resin is preferably polyester, polyphenylene sulfide, polyamide, polypropylene, ethylene vinyl acetate, alicyclic olefin, or acrylic.

The filtering step is a step of separating impurities by filtration from the molten resin produced in the production step. In the filtering step, the molten resin is filtered using the filter medium formed of a material comprising a stainless steel which does not comprise molybdenum. Molybdenum causes precipitation of antimony metal, and therefore, the use of, as the material of the filter medium, the stainless steel not comprising molybdenum can prevent precipitation of antimony metal in the filtering step.

The resin film forming step is a step of forming a resin film from the molten resin from which impurities have been removed in the filtering step. The resin film forming step comprises an extrusion sub-step, a cooling sub-step, a stretching sub-step, and a taking-up sub-step.

The extrusion sub-step is a sub-step of extruding the molten resin filtered in the filtering step from a slit nozzle into a film. The cooling sub-step is a sub-step of cooling the film-shaped molten resin formed by extrusion in the extrusion sub-step. The stretching sub-step is a sub-step of stretching the film-shaped molten resin cooled in the cooling sub-step in any direction at any stretching ratio to give a molten resin film having a desired form. The taking-up sub-step is a sub-step of taking up the resin film stretched in the stretching sub-step in rolls.

### EXAMPLES

### Measurement Method

### (1) Amount of Dissolved Iron

Diantimony trioxide is dissolved in ethylene glycol heated to 110° C. to prepare an ethylene glycol solution containing 2% by weight diantimony trioxide. Into a glass container, 1 L of the ethylene glycol solution containing antimony was placed. In the solution in the container, a test material having a specific surface area of 150 cm² (any of the materials described below, including SUS304L, 304LN, and SUS316L) is immersed. To the container, a reflux condenser is attached, and the test material immersed in the ethylene glycol solution kept at 170° C. in the container is left to stand for 24 hours. After that, the test material is taken from the ethylene glycol solution. In this test, due to the ion-exchange reaction between iron and an antimony compound, antimony metal is precipitated on the test material and an iron ion of the test material is dissolved in the post-reaction solution. The concentration of iron in the solution is determined by the method described below and the obtained value is defined as the amount of the dissolved iron.

### 1. Operation

The post-reaction solution in an amount of 1 g is precisely weighed out and placed into a 100-mL beaker. To this, 5 mL of sulfuric acid is added, and the mixture is heated at about 300° C. using a heater placed under the beaker for carbonation of a carbon compound in the post-reaction solution. To the post-reaction solution, nitric acid is gradually added, and the mixture is maintained at 300° C. for decomposition. After the post-reaction solution turns clear and colorless, the post-reaction solution is heated and concentrated to almost dryness. The almost dried substance is left to stand to be cooled to room temperature, 10 mL of hydrochloric acid is added thereto, and the mixture is heated to about 200° C. for dissolution of the dried substance. The post-reaction solution is cooled to room temperature, placed into a 25-mL measuring flask, and diluted by adding ion-exchanged distilled water to the marked line. In this measurement, a blank test is performed in an operation similar to the above, except that no test material is used, to obtain a blank value.

The solution obtained with the above operation is sprayed into argon plasma, and the amount of iron contained in the solution is measured at a wavelength of 259.94 nm with a high-frequency inductively coupled plasma emission spectrometer to obtain the iron concentration from a calibration curve previously prepared.

Iron concentration (μg/g)=(S−S0)×V/W

Herein, S represents the iron concentration (μg/mL) which is obtained from a calibration curve as a value corresponding to the luminescence intensity of the sample solution, S0 represents the iron concentration (μg/mL) which is obtained from a calibration curve as a value corresponding to the luminescence intensity in the blank test and, V represents a fluid volume (mL) of an acid fluid in which a test material is dissolved, and W represents a fluid volume (g) of ethylene glycol.

### 2. Operation for Preparing Calibration Curve

An iron standard stock solution (1.0 mg Fe/mL) is diluted with hydrochloric acid to prepare iron standard solutions having a concentration in the range of 0 to 20 (μg Fe/mL).

With the use of the iron standard solutions, a calibration curve representing the relation between the iron concentration and the luminescence intensity is prepared.

### 3. Measuring Apparatus

The high-frequency inductively coupled plasma emission spectrometer used in the measurement is a sequential ICP manufactured by Seiko Instruments & Electronics Ltd. (trade name, “SPS1100”).

### (2) Amount of Precipitated Antimony

As described in above (1), a test material having a specific surface area of 150 cm² is immersed in an ethylene glycol solution which contains 2% by weight diantimony trioxide and is maintained at 170° C., and left to stand for 24 hours. Then, the test material is taken from the ethylene glycol solution and the amount of antimony precipitated on the test material is measured with an EPMA method. In the EPMA method, electron beam irradiation to a sample induces the interactions between an irradiated electron and atoms comprised in the sample and thereby generates specific X-rays unique to each element. The number of counts of the specific X-rays unique to each element is measured to obtain the composition of the sample surface (at a depth of about 1 μm).

### (3) Cleaning Method for Filter Member

A used filter member to which a molten thermoplastic resin is adhered is pulled out from a casing and placed into a solvent cleaning tank or a heat treatment tank for removal of the thermoplastic resin. Then, the filter member is immersed in an acid or alkaline aqueous solution and rinsed with water. Ultrasound is applied to both surfaces of the filter member to remove foreign matter adhered to the filter member.

### (4) Recoverability of Filter Member After Cleaning

The recoverability of the used filter member cleaned as described above is determined by measurement of the value of air flow resistance. Air is introduced into the inside of the filter member from the outer surface of the filter member. The flow resistance value at the time of the air introduction is measured in pascals with a mercury manometer, and the obtained value is used to evaluate the recoverability after cleaning. The recoverability of the filter member after cleaning is evaluated by the ratio (%) of the flow resistance value of the used filter to the flow resistance value measured in an unused filter.

### (5) Detection of Foreign Matter Defects on Resin Film Surface

Detection of foreign matter defects with a size of 25 to 150 μm on the resin film surface is performed with a surface defect inspection system equipped with a line sensor camera manufactured by NAGASE & CO., LTD. while a resin film is delivered at a speed of 1 to 15 m/min. Detection results are represented as the number of surface defects per unit area of the filter member (defects/m²).

### (6) Detection of Corrosion in Filter Member

Detection of intergranular corrosion and pitting corrosion is performed by observation of the filter member surface with a scanning electron microscope (SEM).

The resin used was polyethylene terephthalate raw material (IV: 0.62, including 200 ppm antimony polymerization catalyst, 30 ppm trimethyl phosphoric acid (TMPA), 65 ppm magnesium acetate, and silica particles with a diameter of 80 nm). The polyethylene terephthalate raw material was dried under a reduced pressure of 2 mmHg at 170° C. for 2 hours to give a dried PET raw material with an adjusted water absorption rate of 15 ppm. The dried PET raw material was completely melted in the first extruder (length/diameter ratio, i.e. L/D: 25) of a single-screw tandem extruder, and the molten resin was delivered to the second extruder (L/D: 25) of the single-screw tandem extruder. The resin adjusted to a temperature of 285° C. was supplied at a discharge rate of 3 tons/hour from the extruder (81) shown in FIG. 3 to the filter (50) having the filter member (10) shown in FIG. 1. The filter member (10) provided in the filter (50) was one that has 200 filter media made of a sintered metal non-woven fabric having a diameter of 12 inches and a filtering accuracy of 5 μm, and such a filter member was applied in the filter apparatus. The molten resin filtered with the filter (50) was supplied to the film forming machine (82) shown in FIG. 3 having a T die with a width of 2200 mm, and was extruded from a slit nozzle of the die into a film sheet. The film sheet was appressed on the surface of the drum-like cooling machine (83) shown in FIG. 3 having an outside diameter of 1800 mm, a surface temperature of 22° C., and an outer peripheral surface plated with chromium, while electrostatic charge is applied to the surface. Then, the film sheet was delivered through the stretching machine (84) and taken up with the take-up machine (85) to give a resin film having a thickness of 2500 μm. Before the supply of the molten resin to the filter member, the filtration pressure was measured with filtering pressure gauges attached upstream and downstream of a pipe for supplying the molten resin extruded from the extruder (81) to the filter (50). In Comparative Example 1, the material of the filter medium in the filter member was SUS316L, which is conventionally used for a filter medium, and in Examples 1 and 2, the material was SUS304L and SUS304LN, respectively. The lifetime (days) of the filter member, the foreign matter defects on the resin film surface (defects/m²), the recoverability (%) of the filter member after cleaning, the lifetime (days) of the cleaned filter, the existence of corrosion in the filter member, the amount of the precipitated antimony (counts), and the amount of the dissolved iron (ppm) are shown in Table 1.

TABLE 1

| | | | Comparative |
|---|---|---|---|
| | Example 1 | Example 2 | Example 1 |
| | SUS304L | SUS304LN | SUS316L |
| Lifetime of filter member (days) | 45 | 48 | 15 |
| Foreign matter defects on resin | 0 | 0 | 5 |
| film surface (defects/m²) | | | |
| Recoverability of filter member | 95 | 98 | 74 |
| after cleaning (%) | | | |
| Lifetime of cleaned filter (days) | 40 | 41 | 13 |
| Corrosion in filter member | Not | Not | Not |
| | detected | detected | detected |
| Amount of precipitated | 0 | 0 | 8000 |
| antimony (counts) | | | |
| Amount of dissolved iron (ppm) | 5.2 | 5.2 | 40 |

Herein, the lifetime (days) of the filter member represents the number of days for which the molten resin has flown until the filtering pressure reaches 25 MPa. The lifetime (days) of the cleaned filter means the time period to the exchange of the filter medium.

Thus, it is understood that a long lifetime of the filter member can be obtained by using SUS304L or SUS304LN instead of SUS316L as the material of the filter medium. It is also understood that a lifetime of the filter cleaned for reuse as long as that of a new filter can be obtained by using SUS304L or SUS304LN. Moreover, no foreign matter defects are observed on the surface of the resin film obtained in the case of using SUS304L or SUS304LN, and therefore it is also clear that the use of such a material allows formation of an excellent resin film. Furthermore, while the amounts of the precipitated antimony in Examples 1 and 2 are both 0 count, the amount of the precipitated antimony in Comparative Example 1 is 8000 counts, which is significantly large. While the amounts of the dissolved iron in Examples 1 and 2 are both 10 ppm or less, the amount of the dissolved iron in Comparative Example 1 is more than 20 ppm.

### Other Examples

The filter member in the above embodiment comprises a leaf disc filter, but the filter member is not limited to this type and for example, a candle filter, a pack filter, a wire gauze filter, or the like can be used. The filtering accuracy of these types of filters can be selected according to the customer request, and for example, a cut filter with a filtering accuracy of 0.1 to 500 μm may be used. The same will apply to the filtering accuracy of a leaf disc filter.

### INDUSTRIAL APPLICABILITY

As described above, the present invention is useful for a filter medium, a filter provided with the filter medium, and a production method for a resin film using the filter medium.

### REFERENCE SIGNS LIST

10 Filter member
20 Filter medium
30 Filter retainer
40 Hub part
50 Filter
80 Resin film production apparatus
81 Extruder
82 Film forming machine
83 Cooling machine
84 Stretching machine
85 Take-up machine

1. A filter medium for filtration of a molten resin containing antimony, being formed of a material not substantially comprising molybdenum.

2. The filter medium according to claim 1, wherein as a measure of the amount of antimony precipitated on the filter medium taken out after 24-hour immersion in an ethylene glycol solution containing 2% by weight diantimony trioxide kept at 170° C., the number of counts of X-rays at a wavelength specific to antimony generated by electron irradiation to the filter medium in an Electron Probe Micro Analyzer (EPMA) method is 1000 counts or less.

3. The filter medium according to claim 1, wherein the amount of iron dissolved from the filter medium during 24-hour immersion in an ethylene glycol solution containing 2% by weight diantimony trioxide kept at 170° C. is 20 ppm or less.

4. The filter medium according to claim 1, wherein as a measure of the amount of antimony precipitated on the filter medium taken out after 24-hour immersion in an ethylene glycol solution containing 2% by weight diantimony trioxide kept at 170° C., the number of counts of X-rays at a wavelength specific to antimony generated by electron irradiation to the filter medium in an Electron Probe Micro Analyzer (EPMA) method is 1000 counts or less, and wherein the amount of iron dissolved from the filter medium during 24-hour immersion in an ethylene glycol solution containing 2% by weight diantimony trioxide kept at 170° C. is 20 ppm or less.

5. The filter medium according to claim 1, wherein the material contains stainless steel.

6. The filter medium according to claim 5, wherein the stainless steel is an austenitic stainless steel mainly comprising iron, chromium, and nickel as components.

7. The filter medium according to claim 1, wherein the material does not substantially contain manganese or sulfur.

8. The filter medium according to claim 7, wherein the material does not substantially contain aluminum, titanium, phosphorus, silicon, or carbon as a component.

9. The filter medium according to claim 1, wherein the material contains carbon in an amount of 0.08% or less.

10. The filter medium according to claim 1, wherein the material contains at least one or more elements selected from copper, niobium, bismuth, lead, and tellurium.

11. The filter medium according to claim 1, wherein the material is a single material or a composite material selected from SUS304, SUS304L, SUS304LN, SUS304Cu, SUS304N1, SUS304N2, SUS304J1, SUS304J2, SUS304BF, SUS304FL, SUS347, SUS321, SUS630J2, ASK3000T, and SUSXM15J1.

12. The filter medium according to claim 1, having been subjected to a surface treatment selected from chrome plating, nickel plating, copper plating, ceramic composite nickel plating, titanium nitride sputtering, and silicon carbide sputtering or a composite treatment thereof.

13. The filter medium according to claim 1, wherein the molten resin is a thermoplastic resin.

14. The filter medium according to claim 1, wherein the material is a sintered metal non-woven fabric formed by processing of a metal wire into a fiber and then sintering of the resulting fibrous metal wire.

15. A filter member provided with the filter medium according to claim 1.

16. The filter member according to claim 15, being a leaf disc filter, a candle filter, or a pack filter.

17. A resin film production method comprising a step of producing a molten resin containing antimony, a step of filtering the molten resin produced in the production step, and a step of forming a resin film from the molten resin filtered in the filtration step, the filtration step being a step of filtering the molten resin using a filter medium formed of a material not substantially comprising molybdenum.
